(19) United States
(12) Patent Application Publication
(10) Pub. No.: US 2010/0143644 A1
(43) Pub. Date: Jun. 10, 2010

(54) APPARATUS AND METHOD FOR SOLIDIFYING A MATERIAL UNDER CONTINUOUS LAMINAR SHEAR TO FORM AN ORIENTED FILM

(76) Inventors: Alejandro Marangoni, Puslinch (CA); Fatemeh Maleky, Kitchener (CA); Stefan Idziak, Waterloo (CA); Gianfranco Mazzanti, Beechville (CA)

Correspondence Address: VALENTINE A COTTRILL;SUSAN TANDAN, 50 QUEEN STREET NORTH, STE. 1020, P.O. BOX 2248, KITCHENER, ON, N2H6M2, CA

(21) Appl. No.: 12/594,009

(22) PCT Filed: Mar. 28, 2008
(86) PCT No.: PCT/CA08/00594

§ 371 Date: Feb. 16, 2010

Related U.S. Application Data
(60) Provisional application No. 60/907,382, filed on Mar. 30, 2007.

(51) Int. Cl. B32B 5/12; B29C 47/08; B29C 47/00

(52) U.S. Cl. 428/114; 425/113; 264/176.1

(57) ABSTRACT

A method of solidifying a fluid comprising a material into an oriented film. The method includes pumping the fluid into a channel at an input end thereof at a predetermined pressure sufficient to push the material to an output end of the channel. The channel is at least partially defined by a substantially smooth outer surface of an inner tube and a substantially smooth inner surface of an outer tube. The method also includes subjecting the material to laminar shear at a predetermined rate by rotating one of the inner tube and the outer tube relative to the other. The predetermined rate is selected to promote solidification of the fluid into the oriented film. Also, the method includes cooling the material at a predetermined rate as the material moves through the channel from the input end to the output end to promote solidification of the fluid into the oriented film.

### FIELD OF THE INVENTION

The present invention is an apparatus and a method for solidifying a material under continuous laminar shear into an oriented film.

### BACKGROUND OF THE INVENTION

In certain materials (e.g., fats, proteins, polysaccharides, and gels thereof), sensorial attributes and macroscopic properties are influenced by such features as colloid size and shape (and the structure and spatial distribution of the colloidal network) or polymer size and shape, as the case may be. Such macroscopic properties include, for example, melting point, texture, and visual appearance. For example, it is known that the structure of the crystal network of a fat and mechanical properties thereof are affected by processing conditions, e.g., rate of cooling, shear rate (if any), the degree of undercooling, and annealing time, although the mechanisms involved are not necessarily well understood.

It is also known that certain fats (e.g., cocoa butter) may exist in different crystalline forms (i.e., with different types of crystal packing and thermodynamic stabilities), and that the crystallization of fats plays a critical role in determining the physical and thermal properties of food products which include these fats. In particular, the optimal polymorph in chocolate manufacturing is identified as βV. This form is the stable polymorphic phase with a melting point that is sufficiently high to be stored at room temperature, but that is also low enough that chocolate becomes a smooth liquid when heated in the mouth. In addition, the βV form gives a clean “snap” (or break), a glossy appearance, and desirable coloring to chocolate.

However, the βV form is not obtained in bulk chocolate by simple cooling of a substantially static volume of liquid chocolate. (Strictly speaking, the “liquid” is a mixture which generally includes solid particles, as is well known.) It has been found that subjecting the liquid to shear stresses while the liquid is cooling can accelerate (or promote) production of the desired polymorphic phase. As is well known in the art, a scraped surface heat exchanger is commonly used to provide the βV form. In the scraped surface heat exchanger, the material is turbulently mixed and simultaneously subjected to relatively high shear stresses, until the desired crystallization has been achieved. In the course of such processing, some very unstable phases are produced, and in some circumstances, the additional step of “tempering” is required in order to achieve the desired crystallization. Typically, the optimum parameters are determined by trial and error. Accordingly, the scraped surface heat exchanger has some disadvantages.

An attempt to provide a means for better control of partial crystallization is disclosed in U.S. Pat. No. 5,264,234 (Windhab et al.), which discloses an apparatus with certain features for control of the temperature of the cocoa butter while the cocoa butter is subjected to shear stresses. In the apparatus, a rotor (21) including a “flat spiral screw” (22) is positioned inside a stationary cylinder having an inner cooling wall and an outer cooling jacket (col. 5, lines 16-21). Cocoa butter, in liquid form, is introduced into the gap between the rotor and the stationary cylinder. However, because of the flat spiral screw (22) on the rotor, only “pre-crystallized” liquid material is produced (col. 4, lines 17-20):
The pre-crystallized substance leaves the mechanism with a specifically fixed viscosity, and in a state directly susceptible to processing and finishing (no subsequent reheating is needed).

Accordingly, although Windhab et al. discloses a device which is intended to provide for better control of partial crystallization, turbulent shear is applied, resulting in a non-solid product.

It has been proposed that subjecting liquid cocoa butter (or similar material) to laminar shear may provide better control over the process, and may be more efficient. However, the devices for crystallization of fats under laminar shear which have been developed have some disadvantages. These devices are as follows.
(i) MacMillan et al. (2002) disclose a device in which two plates (one stationary, and the other rotating) are positioned on a central axis and utilized to subject cocoa butter to predetermined shear stresses, to crystallize the cocoa butter. The plates are a stationary cone and a rotatable flat plate. The device includes means for heating and cooling the material between the plates substantially uniformly. In the device disclosed, the gap between the disks widens as the distance from the central axis increases, so that the shear stress to which the cocoa butter is subjected is substantially constant, i.e., approximately the same at any particular radial distance from the center axis. However, it appears that this device could only be used for batch production.
(ii) In Mazzanti et al. (2004, 2005), a device is disclosed in which two concentric cylinders are positioned vertically, and in which the inner cylinder is stationary and the outer cylinder rotates. The oil (i.e. the fat, in liquid form) is introduced into a gap between the two cylinders, and the oil is subjected to shear stresses due to the rotation of the outer cylinder. The device includes means for heating and cooling the material between the cylinders substantially uniformly. However, this device appears to be adapted only for production of a batch product.

These devices have various disadvantages. For instance, the MacMillan et al. and the Mazzanti et al. devices appear to be adapted only to produce batches, i.e., they are experimental devices for use in a laboratory which are not adapted for continuous (or substantially continuous) production.

### SUMMARY OF THE INVENTION

In view of the problems in the prior art described above, there is a need for an apparatus and a method adapted for solidifying a material under continuous laminar shear to form an oriented film thereof.

As used in this description and in the appended claims, the following words and phrases (and forms of such words and phrases) shall be defined to have the following meanings.

Fluid “Fluid” is intended to have a relatively broad meaning, referring to a liquid and/or a mixture of a liquid and solid particles.

Solidify “Solidify” is intended to have a relatively broad meaning, referring to the change of a material from fluid into solid, whether by crystallization (e.g., if the material is a fat), cross-linking, gelation, setting, or otherwise.

Oriented Film “Oriented film” is meant to have a relatively broad meaning, referring to a film of colloidal particles (including, e.g., crystals) or polymers (as the case may be) substantially aligned, in substantially the same direction.

In its broad aspect, the invention provides an apparatus for solidifying a fluid comprising a material to form an oriented film. The apparatus includes an inner tube substantially symmetrical with respect to an axis thereof, the inner tube having an outer diameter defined by a substantially smooth outer surface thereof and an inner diameter defined by an inner surface thereof, and an outer tube substantially symmetrical with respect to the axis, the outer tube comprising an inner diameter defined by a substantially smooth inner surface thereof. The inner and outer tubes are positioned substantially coaxially to at least partially define a channel therebetween, the channel extending between input and output ends thereof. Also, a selected one of the tubes is adapted for rotation thereof about the axis so that the selected tube is movable relative to the other of the tubes. The fluid is injectable into the channel at the input end under a predetermined pressure sufficient to push the material to the output end, so that the material is subjected to laminar shear at a predetermined rate due to rotation of the selected tube at a preselected speed. The predetermined rate is selected to promote solidification of the fluid into the oriented film as the material moves through the channel toward the outer end. The apparatus also includes a heat transfer subassembly for modifying the material's temperature to promote solidification of the fluid into the oriented film.

The apparatus, in one embodiment, is adapted to provide for non-uniform modification of the material's temperature over the length of the channel, i.e., from the input end to the output end.

In another aspect, the heat transfer subassembly is for cooling the material in the channel in a predetermined manner to promote solidification of the fluid into the oriented film.

In another of its aspects, the heat transfer subassembly is adapted to cool the material in accordance with one or more preselected temperature gradients along one or more respective preselected lengths of the channel to promote solidification of the fluid into the oriented film.

In another of its aspects, the invention provides a method of solidifying a fluid comprising a material to form an oriented film. The method includes the step of pumping the fluid into a channel at an input end thereof at a predetermined pressure sufficient to push the material to an output end of the channel. The channel is at least partially defined by a substantially smooth outer surface of an inner tube and a substantially smooth inner surface of an outer tube. Also, the method includes the step of subjecting the material to laminar shear at a predetermined rate by rotating one of the inner tube and the outer tube relative to the other, the predetermined rate being selected to promote solidification of the fluid into the oriented film. In addition, the method includes the step of cooling the material at a predetermined rate as the material moves through the channel from the input end to the output end to promote solidification of the fluid into the oriented film.

In one embodiment, it is preferred that the material is subjected to laminar shear at substantially the same time as it is cooled.

In another aspect, the material in the channel is cooled by transporting a heat transfer fluid through one or more conduits positioned proximal to the channel to facilitate heat transfer from the material in the channel to the heat transfer fluid.

In yet another aspect, the material in the channel is cooled by transporting a heat transfer fluid through a number of conduits positioned proximal to the channel. Each conduit is positioned proximal to a preselected length of the channel respectively, and the heat transfer fluid has a preselected initial temperature upon introduction thereof into each conduit respectively to facilitate heat transfer from the material in the channel to the heat transfer fluid.

In another aspect, the material in the channel is cooled by pumping the heat transfer fluid in each conduit respectively in an overall direction substantially away from the output end and toward the input end.

In another of its aspects, the invention provides an oriented film solidified from a fluid comprising a material. The oriented film is produced by pumping the fluid into a channel at an input end thereof at a predetermined pressure sufficient to push the material to an output end of the channel. In addition, the material is subjected to laminar shear at a predetermined rate by rotating one of the inner tube and the outer tube relative to the other, to promote solidification of the fluid into the oriented film. Also, the material is cooled at a predetermined rate as the material moves through the channel from the input end to the output end to promote solidification of the fluid into the oriented film.

In another aspect, the invention provides an apparatus for solidifying a fluid comprising a material to form an oriented film. The apparatus includes an inner tube and an outer tube positioned substantially coaxially to at least partially define a channel therebetween, the channel extending between input and output ends thereof. A selected one of the tubes is adapted for rotation thereof about the axis of the tubes so that the selected tube is movable relative to the other of the tubes. The fluid is injectable into the channel at the input end under a predetermined pressure sufficient to push the material to the output end, so that the material is subjected to laminar shear as the material moves through the channel toward the outer end due to movement of the selected tube relative to the other said tube, the laminar shear at least partially causing the fluid to solidify into the oriented film. The apparatus also includes a heat transfer subassembly for modifying the material's temperature to promote solidification of the fluid into the oriented film.

### BRIEF DESCRIPTION OF THE DRAWINGS

The invention will be better understood with reference to the drawings, in which:

FIG. 1A is a cross-section of an embodiment of an apparatus of the invention;

FIG. 1B is a portion of the cross-section of FIG. 1A, drawn at a larger scale;

FIG. 1C is a cross-section taken along line A-A in FIG. 1A;

FIG. 2A is a cross-section of another embodiment of the apparatus of the invention, drawn at a smaller scale;

FIG. 2B is a portion of the cross-section of FIG. 2A, drawn at a larger scale;

FIG. 2C is a schematic illustration showing temperature gradients for material moving through the channel in an embodiment of an apparatus of the invention;

FIG. 2D is a cross-section of part of a water jacket of the invention, drawn at a larger scale;

FIG. 3 is a schematic illustration of an embodiment of the apparatus of the invention;

FIG. 4 is a cross-section of another embodiment of the apparatus of the invention, drawn at a smaller scale;

FIG. 5A is a schematic illustration of an embodiment of a method of the invention;

FIG. 5B is a graph showing the temperature gradients for a cocoa butter sample;

FIG. 5C a graph showing the temperature gradients for a sample of a binary mixture of cocoa butter and milk fat;

FIG. 5D a graph showing the temperature gradients for a Palmel 26 sample;

FIG. 6A is a graph showing crystallization curves for cocoa butter;

FIG. 6B is a graph showing crystallization curves for a binary mixture of cocoa butter and milk fat;

FIG. 6C is a graph showing crystallization curves for Palmel 26;

FIG. 7A is a representation of X-ray diffraction patterns in wide angle scattering (WAXS) of cocoa butter crystallized under certain conditions;

FIG. 7B is a representation of X-ray diffraction patterns in wide angle scattering (WAXS) of the binary mixture of cocoa butter and milk fat under certain conditions;

FIG. 8A is a representation of X-ray diffraction patterns in small angle scattering (SAXS) and wide angle X-ray scattering (WAXS) for cocoa butter under certain conditions;

FIG. 8B is a representation of X-ray diffraction patterns in small angle scattering (SAXS) and wide angle X-ray scattering (WAXS) for the binary mixture of cocoa butter and milk fat under certain conditions;

FIG. 9A is a representation of X-ray diffraction patterns in small angle scattering (SAXS) and wide angle X-ray scattering (WAXS) of Palmel 26 crystallized in the absence of shear;

FIG. 9B is a representation of X-ray diffraction patterns in small angle scattering (SAXS) and wide angle X-ray scattering (WAXS) of Palmel 26 crystallized according to the method of the invention;

FIG. 10A is a melting thermogram for cocoa butter under certain conditions;

FIG. 10B is a melting thermogram for the binary mixture of cocoa butter and milk fat under certain conditions;

FIG. 10C is a melting thermogram for Palmel 26 under certain conditions;

FIG. 11 is a schematic illustration of crystalline orientation in YZ and XZ planes;

FIG. 12A is a representation of an X-ray diffraction pattern of the form V polymorph for cocoa butter in both SAXS and WAXS crystallized without shear;

FIG. 12B is a representation of an X-ray diffraction pattern of the form V polymorph for cocoa butter in both SAXS and WAXS crystallized according to the method of the invention;

FIG. 13A is a representation of an azimuthal plot X-ray diffraction pattern of the β phase of cocoa butter crystallized according to the method of the invention;

FIG. 13B is a representation of an azimuthal plot X-ray diffraction pattern of the β phase of the binary mixture of cocoa butter and milk fat crystallized according to the method of the invention;

FIG. 13C is a representation of an azimuthal plot X-ray diffraction pattern of the β phase of Palmel 26 crystallized according to the method of the invention;

FIG. 13D is a representation of an azimuthal plot X-ray diffraction pattern of the β phase of cocoa butter crystallized in static conditions;

FIG. 13E is a representation of an azimuthal plot X-ray diffraction pattern of the β phase of the binary mixture of cocoa butter and milk fat crystallized in static conditions; and

FIG. 13F is a representation of an azimuthal plot X-ray diffraction pattern of the β phase of Palmel 26 crystallized in static conditions.

### DETAILED DESCRIPTION

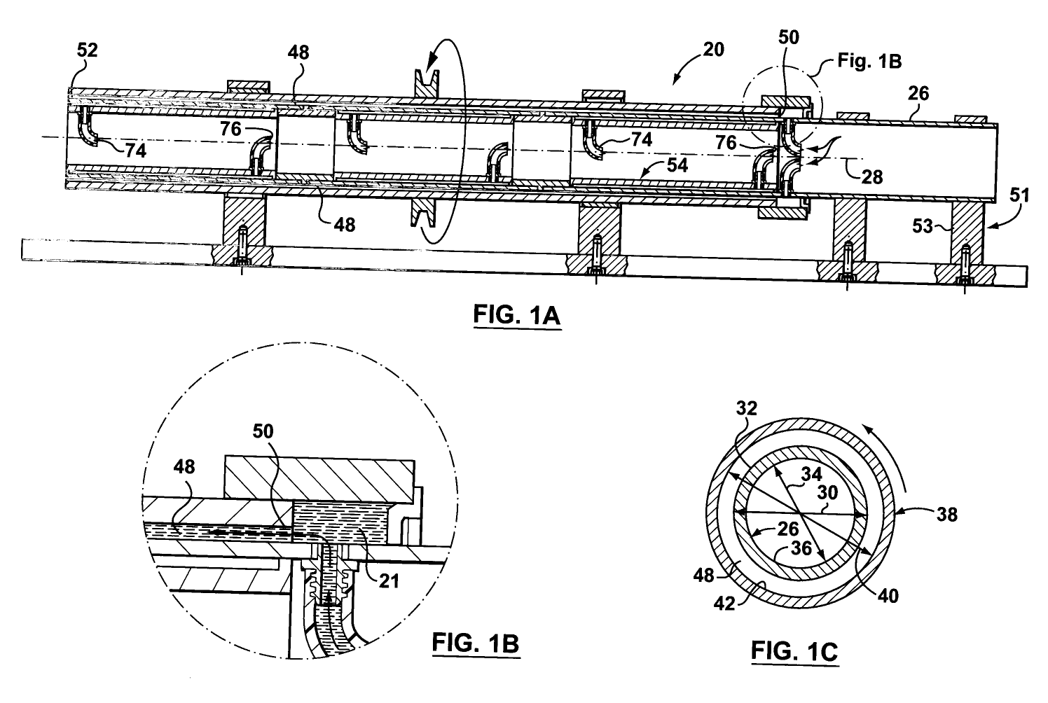

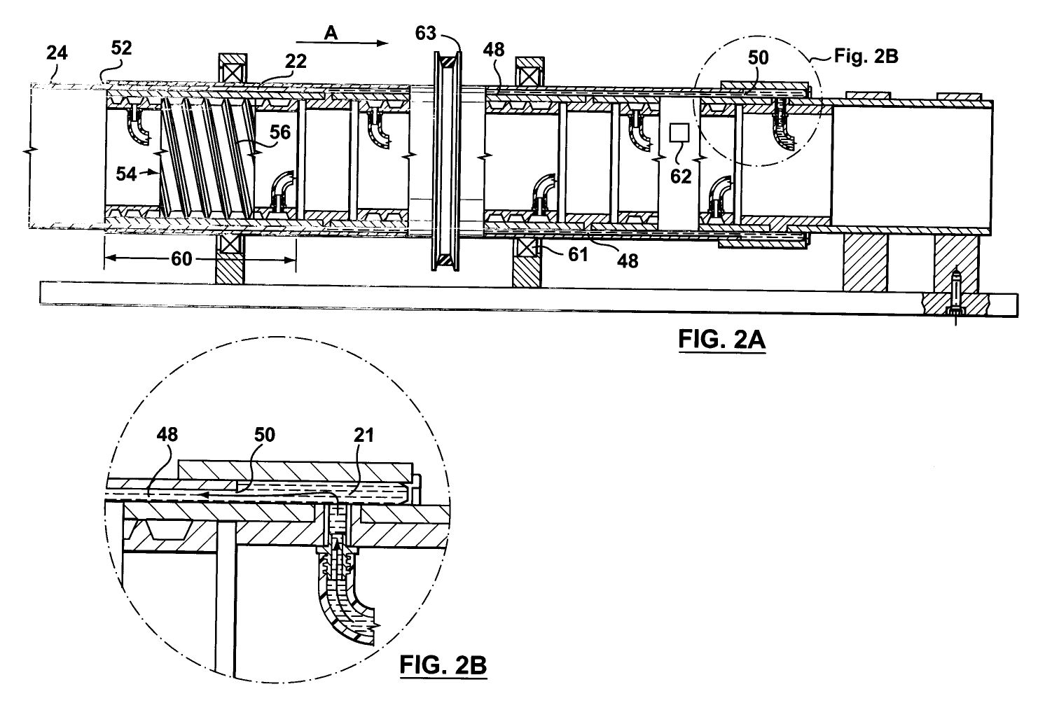

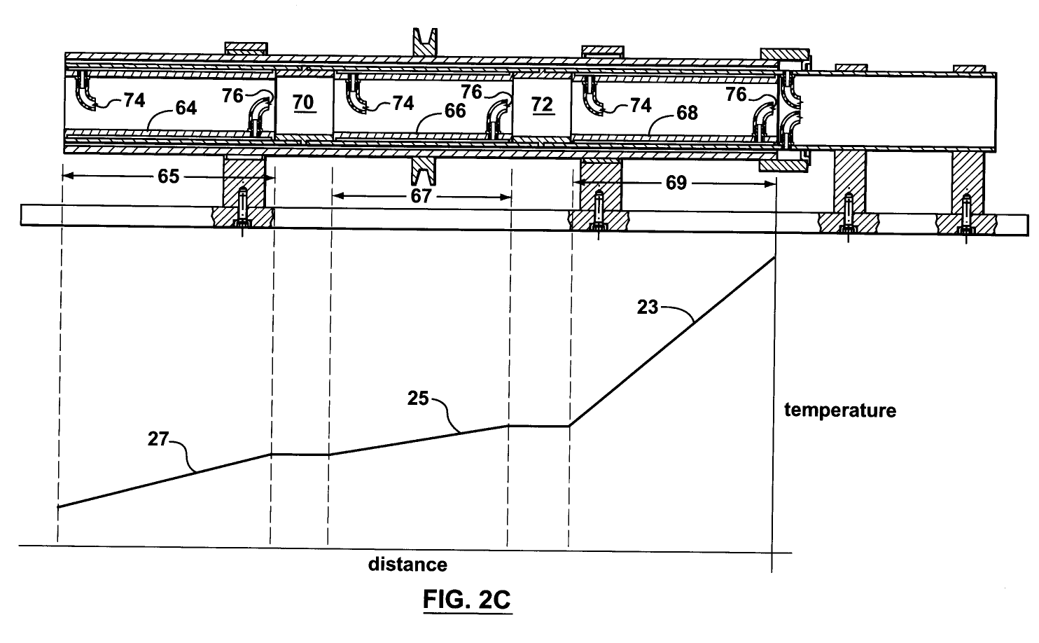

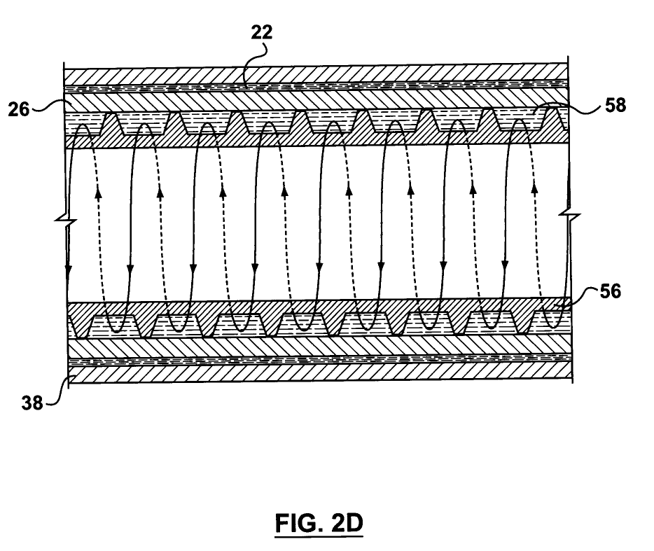

Reference is first made to FIGS. 1A-3 to describe an embodiment of an apparatus of the invention generally indicated by the numeral 20. The apparatus 20 is for solidifying a fluid 21 comprising a material 22 to form an oriented film 24 (FIG. 2A). In one embodiment, the apparatus 20 includes an inner tube 26 which is substantially symmetrical with respect to an axis 28 thereof (FIGS. 1A, 2A). The inner tube 26 preferably has an outer diameter 30 defined by a substantially smooth outer surface 32 thereof and an inner diameter 34 defined by an inner surface 36 thereof (FIG. 1C). As can be seen in FIGS. 1A and 1C, the apparatus 20 preferably additionally includes an outer tube 38 which is also substantially symmetrical with respect to the axis 28. Preferably, the outer tube 38 has an inner diameter 40 defined by a substantially smooth inner surface 42 thereof. It is preferred that the inner and outer tubes 26, 38 are positioned substantially coaxially, and at least partially define a channel 48 therebetween which extends between input and output ends thereof 50, 52. Preferably, a selected one (or more) of the tubes 26, 38 is adapted for rotation thereof about the axis 28 so that the selected tube is movable relative to the other of the tubes 26, 38, as will be described. It is also preferred that the fluid 21 is injectable into the channel 48 at the input end 50 under a predetermined pressure which is sufficient to push the material 22 to the output end 52. As will also be described, the material 22 is subjected to laminar shear at a predetermined rate due to rotation of the selected one (or more) of the tubes 26, 38 at a preselected speed. The predetermined rate of laminar shear is selected to promote solidification of the fluid 21 into the oriented film 24 as the material 22 moves through the channel 48 toward the output end 52. The apparatus 20 preferably also includes a heat transfer subassembly 54 for modifying the material's temperature to promote solidification of the fluid into the oriented film.

Preferably, the channel 48 is substantially uniform between the input and output ends 50, 52, to promote solidification of the fluid 21 into the oriented film 24. As can be seen in FIGS. 1A, 1C and 2A, the inner surface 42 of the outer tube 38 and the outer surface 32 of the inner tube 36 preferably are substantially parallel to each other.

It is also preferred that the heat transfer subassembly 54 is for cooling the material 22 in the channel 48 in a predetermined manner to promote solidification of the fluid 21 into the oriented film 24. Preferably, the heat transfer subassembly 54 includes one or more conduits 56 (FIG. 2A) positioned proximal to the channel 48. Specifically, the conduits 56 preferably are positioned proximal to (i.e., in contact with) the inner surface 36 of the inner tube 26. The heat transfer subassembly 54 preferably also includes a heat transfer fluid (indicated generally by the numeral 58) transportable through the conduit 56 to facilitate heat transfer between the material 22 in the channel 48 and the heat transfer fluid 58. In one embodiment, the heat transfer fluid is directed through the conduits 56 substantially from the output end 52 to the input end 50, i.e., generally in the direction indicated by arrow “A” in FIGS. 1A and 2A.

The heat transfer subassembly 54 preferably is adapted to cool the material 22 in the channel 48 in accordance with one or more preselected temperature gradients to promote solidification of the fluid 21 into the oriented film 24. Three such temperature gradients are generally identified by reference numerals 23, 25, 27 and schematically illustrated in FIG. 2C. As can be seen in FIG. 2C, the material preferably is subjected to non-uniform heat transfer (i.e., heat transfer at varying rates) as the material moves from the input end to the output end. It will be understood that any reasonable number of temperature gradients along the channel could be used. In FIG. 2C, for clarity of illustration, only three temperature gradients are shown.

Preferably, the heat transfer fluid 58 is introduced into the conduit 56 at a predetermined temperature, for cooling the material 22 in the channel 48 to a predetermined extent to promote solidification of the fluid 21 into the oriented film 24. It is also preferred that the heat transfer subassembly includes a number of conduits 56. Preferably, each of the conduits 56 is positioned proximal to a preselected length 60 of the channel 48 (FIG. 2A). The heat transfer fluid is transportable through each conduit 56 respectively to facilitate heat transfer from the material 22 in the channel 48 to the heat transfer fluid.

For example, as can be seen in FIG. 2C, in the embodiment shown therein, the heat transfer subassembly 54 includes three separate water jackets 64, 66, and 68, each positioned respectively adjacent to preselected lengths 65, 67, and 69 of the channel 48. Although the water jackets 64 and 66, and 66 and 68, are shown as being separated by gaps 70, 72 respectively, it will be understood that, based on the temperature gradients sought to be achieved along each preselected length, the water jackets of the heat transfer subassembly 54 may or may not be separated by such gaps. FIG. 2C is schematic, and the temperature gradients shown in FIG. 2C are representative only, meant to show the non-uniformity of variation in the material's temperature from the input end (at the right, as presented in FIG. 2C) to the output end (at the left, as presented in FIG. 2C).

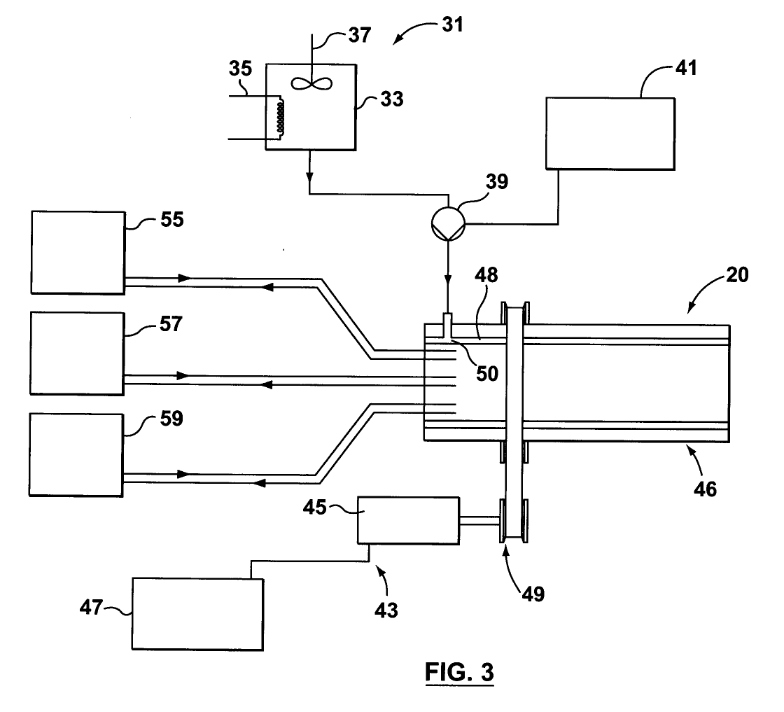

In one embodiment, as schematically illustrated in FIG. 3, the apparatus 20 preferably includes a feed unit 31 with a reservoir 33. The reservoir 33 includes a heater 35 and a mixer 37 for keeping the temperature of the fluid 21 substantially constant, and to provide a quantity of fluid 21 ready to be pumped into the channel 48. The apparatus 20 preferably also includes a pump 39 for pumping the fluid 21 into the channel 48 at the input end 50. Control of the rate at which the fluid 21 is pumped into the channel 48 is important because the rate should be within a certain range. Accordingly, the pump 39 preferably is controlled by a controller 41, as is known in the art.

As described above, in one embodiment, the selected one of the tubes 26, 38 is rotatable relative to the other of the tubes 26, 38. It will be evident to those skilled in the art that, if preferred, each of the tubes could be movable relative to the other. For example, if the tubes were rotated in opposite directions, relatively high rates of laminar shear could be achieved. However, for the sake of simplifying the structure of the apparatus 20, it is preferred that only one of the inner and outer tubes 26, 38 rotates about the axis, while the other tube is substantially stationary. In one embodiment, it is preferred (for practical reasons, described below) that the outer tube 38 is rotatable about the inner tube 26, and the inner tube 26 is held substantially stationary. Such embodiment is shown in FIGS. 1A and 2A.

The apparatus 20 also preferably includes a power unit 43 (FIG. 3), for rotating the outer tube 38 about the axis 28 (FIGS. 1A, 2A). The power unit 43 preferably includes an electromotor 45 operable at variable speeds and controlled by a controller 47 therefor (FIG. 3). The rate of rotation of the outer tube 38 (as well as the size of the channel 48) determines shear rate, so close control of the rate of rotation is desirable. Finally, the power unit 43 also includes a transmission subassembly 49, for operably connecting the motor 45 and the outer tube 38 (FIG. 3).

The inner tube 26 and the outer tube 38 are included in a shearing unit 46 of the apparatus 20. It is preferred that the inner and outer tubes 26, 38 are substantially horizontally positioned. Preferably, the inner tube 26 is mounted to a base 51 via legs 53 to provide a cantilever-type structure (FIG. 1A). This structure provides the benefit that the oriented film 24 can relatively easily be removed at the output end 52. The outer tube 38 preferably is mounted on bearings 61, as is known in the art.

Those skilled in the art would be aware that various liquids may be used as the heat transfer fluid. However, it is preferred that water is used as the heat transfer fluid. As illustrated in FIG. 3, in one embodiment, it is preferred that the heat transfer subassembly 54 includes the three separate water jackets 64, 66, 68. Various arrangements are possible, but it is preferred that such water jackets 64, 66, 68 are sized and positioned as illustrated in FIG. 2C. In order for each water jacket to provide an individual temperature gradient (FIG. 2C), the apparatus 20 preferably includes separate water reservoirs 55, 57, 59 (FIG. 3). Preferably, the water jackets are made of any suitable material, with suitable heat transfer characteristics. For example, the water jackets preferably are made of high-density polyethylene to minimize heat transfer from the heat transfer fluid to the air inside the inner tube 26. Also, high-density polyethylene is used because of its relatively low density. Preferably, the water flows through each water jacket in a substantially spiral (helical) path (FIG. 2D).

Those skilled in the art would also be aware that certain fluids (e.g., uncooked starch suspensions (e.g., corn or tapioca) and protein solutions or suspensions (e.g., egg white, whey protein solutions), and combinations of these with other ingredients in complex food mixtures) solidify when subjected to laminar shear and when heated appropriately. Accordingly, the heat transfer subassembly may be used to heat such material in the channel to promote solidification thereof into the oriented film. It is believed that non-uniform heating of the material as it is moving through the channel and subjected to laminar shear would provide advantageous results, i.e., acceleration of solidification.

As can be seen in FIGS. 1A and 2C, in each water jacket, the heat transfer fluid preferably is pumped into the water jacket at an inlet 74. If desired, each water jacket may have an outlet 76 to permit the heat transfer fluid 58 to be directed away from the inner and outer tubes, so that the heat transfer fluid may be cooled, and recycled, to be reintroduced at the inlet 74 once cooled. Alternatively, the heat transfer fluid 58 may be directed consecutively from one water jacket to the next, as required. Various alternative arrangements will occur to those skilled in the art.

Preferably, upon introduction of the heat transfer fluid 58 into each conduit (i.e., each water jacket) respectively, the heat transfer fluid 58 has a preselected initial temperature. The preselected initial temperature is selected for cooling the temperature of the material 22 in each preselected length of the channel to a preselected extent respectively, to promote solidification of the fluid into the oriented film. It is also preferred that the preselected initial temperature of the heat transfer fluid 58 for each conduit (i.e., each water jacket) is respectively determined according to the position of each conduit relative to the input and output ends 50, 52 of the channel 48. For example, and as can be seen in FIG. 2C, it may be advantageous for the material 22 in the preselected length 65 which is proximal to the water jacket 64 to be cooled at a relatively rapid rate, which situation is schematically illustrated in FIG. 2C. It also may be advantageous to cool the material in the preselected lengths 67, 69 which are adjacent to the water jackets 66, 68 respectively at a slightly lower cooling rate. Introducing the heat transfer fluid 58 into the water jacket 64 at a relatively low temperature, for example, would enable the relatively steep temperature gradient associated with the first water jacket 64 to be achieved. It may also be advantageous for the heat transfer fluid to be directed through the water jackets generally from the output end 52 to the input end 50.

Accordingly, the apparatus provides for non-uniform temperature modification along the channel. As will be described in connection with Examples I-III below, the ability to control the temperature of the material so that the temperature is modified at preselected rates at preselected locations in the channel accelerates solidification into the desired (i.e., most stable) crystal form to be achieved. This shows that non-uniform modification of the material's temperature as it moves through the channel and is subjected to laminar shear accelerates solidification into the oriented film.

Preferably, the outer tube 38 additionally includes one or more ports 62 for permitting sampling of the material in the channel. Preferably, the port 62 is a small door through which material in the channel can be sampled, and which is otherwise usually closed. This can be useful for monitoring solidification of the fluid into the oriented film.

Although various arrangements are possible, it is preferred that the transmission subassembly 49 includes an engagement portion 63 for engagement with a belt (not shown) driven by the motor 45, as is known.

### Sample Apparatus

A sample apparatus was built. The main design inputs to calculate the dimensions of the sample apparatus are the shear rate, feed rate, crystallization (solidification) time and the cooling (or heating) rate. A constant thickness for the material (in the channel) was assumed, and the effective machine length was also assumed based on the time that is necessary for the sample to undergo continuous shear deformation. (The shearing time can be changed if the feed rate changes.)

The design parameters are defined as follows:

Shear rate: γ=1000 s⁻¹

Fat film thickness: δ=1.5 mm

Feed velocity: V_{feed}=1 mm/s

Crystallization length: L_{tube}=800 mm

Based on design inputs, and considering that the inner diameter of the water jackets was to be large enough to provide enough space for water pipes and connectors, the main dimensions of the different parts of the crystallizer were selected and are presented in Table 1. The outer diameters of the inner tube, water jackets and the connectors were sized according to designed values.

TABLE 1
The specifications of the tubes, the connectors, and
the water jackets

| | | Inner | | Outer | | | |
|---|---|---|---|---|---|---|---|
| | | diameter | | diameter | | Weight | |
| Part | Material | Inch | mm | inch | mm | lb/ft | Kg/m |
| Outer tube | Steel | 3.75 | 95.25 | 4 | 101.6 | 6.66 | 9.9 |
| Inner tube | Aluminum | 3.0 | 76.2 | 3.625 | 92.075 | 1.328 | 1.976 |
| Water jacket | Teflon | 2.375 | 60.325 | 3.0 | 76.2 | 0.810 | 1.1 |
| Connector | Aluminum | 2.5 | 63.5 | 3.00 | 76.2 | 1.953 | 2.906 |

The gap (i.e., the channel) between the two tubes, along with the rotating velocity of the outer tube, determines the shear rate.

$$\dot{γ} = \frac{{V}_{shear}}{δ} \qquad ( 1.1 )$$

where γ is the shear rate, Vₛₕₑₐᵣ is the shear velocity and δ is the gap between tubes. The gap is open at the outlet end and is sealed by a high pressure rotary seal at the inlet end to prevent leakage of the oil.

The relation between shear velocity and rotating speed of the outer tube were obtained from shear rate and the gap between the tubes:

$$ω = \frac{{V}_{shear}}{{r}_{{i}_{outertube}}} \qquad ( 1.2 )$$

Substituting the defined values into Eq. (1.1) and (1.2) results in Vₛₕₑₐᵣ=1.5 m/s and ω=300 rpm.

The liquid oil is under shear and is crystallized for a short period of time, this crystallization time is determined from equation 1.3:

$$t = \frac{{V}_{feed}}{{L}_{tube}} \qquad ( 1.3 )$$

L_{tube} used in Eq. (1.3) is the part of the tubes which is directly used for the crystallization process (shearing and cooling), where oil is pumped into the gap between the two tubes. Using the proposed feeding speed, the crystallization time is obtained, 800 seconds. This crystallization time can be increased by reducing the feed rate, if it is required to crystallize the fat for a longer period of time.

In the sample apparatus, the heat transfer subassembly was divided into three segments of uneven lengths. The first segment was the shortest one (150 mm). This segment was used to cool the oil from melting temperature to the onset of crystallization. The second and the third segments were longer, 250 mm and 300 mm, respectively, providing longer crystallization paths for the fat when shear is applied. Water jackets were connected to each other by 50 mm connectors. Water jackets were made of high density polyethylene to prevent heat transfer between cooling water and the air inside the inner tube and also to decrease the total weight of the inner tube that contained the water jackets. The water flowed around each jacket in a spiral path provided by a thread and cooled the inner tube and the oil (FIG. 2D).

As is known, the Reynolds number (Re) is used as a criterion for laminar and turbulent flow. The limit of stability for laminar flow in the channel is determined by the following:

$$Re \sqrt{\frac{δ}{{r}_{i}}} < 41.3 \qquad ( 2 )$$

where rᵢ is the radius of the inner tube and δ is the distance between the inner and outer tubes.

The Reynolds number calculated from the equation (1.4) for the sample apparatus, for the examples described below (i.e., Examples I, II, and III) shows that the fat flow through the channel between the inner and outer tubes is laminar.

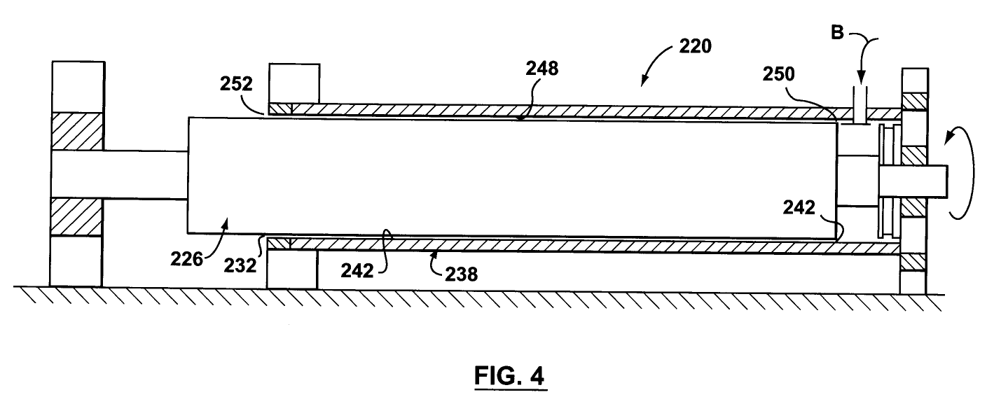

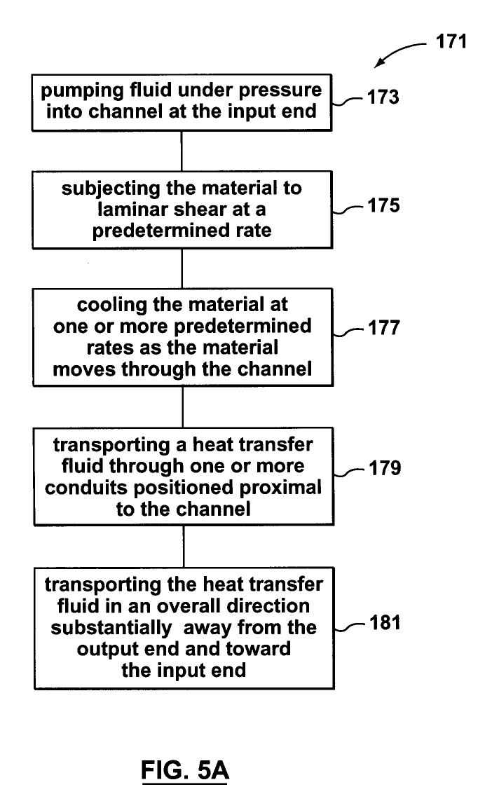

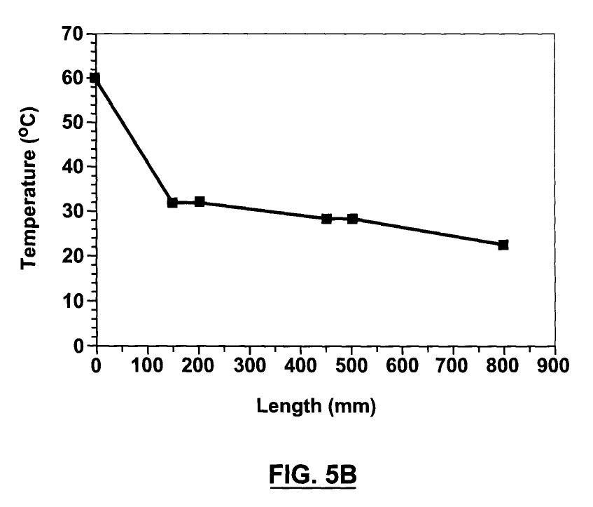

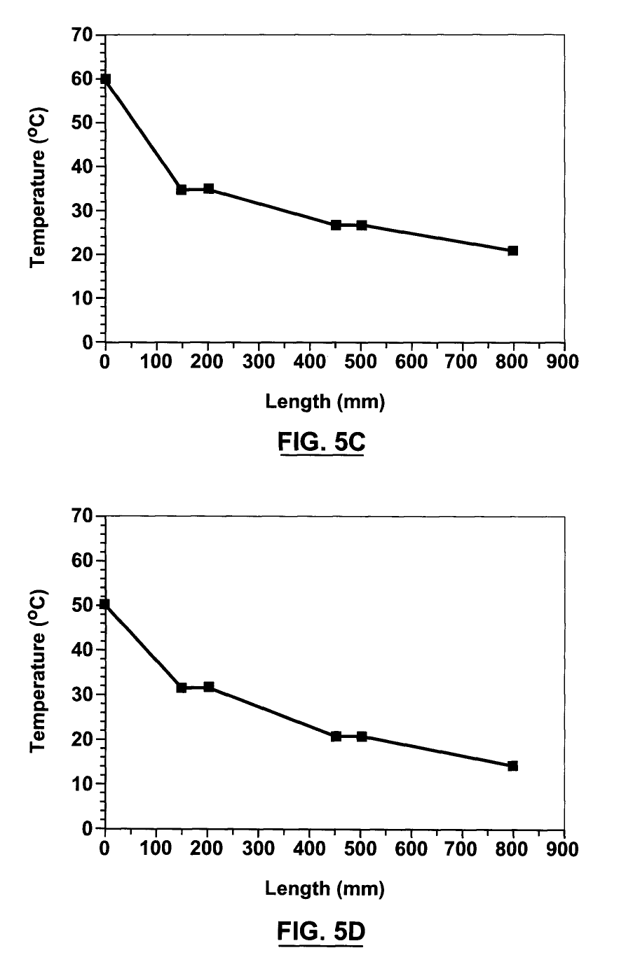

Additional embodiments of the invention are shown in FIGS. 4 and 5A. In FIGS. 4 and 5A, elements are numbered so as to correspond to like elements shown in FIGS. 1A-3.

In another embodiment of the apparatus 220 of the invention, shown in FIG. 4, the apparatus 220 includes an inner tube 226 and an outer tube 238 which is substantially coaxial with the inner tube 226. In this embodiment, it is preferred that the inner tube 226 rotates about the axis 228, and the outer tube 238 is substantially stationary. Preferably, the inner and outer tubes 226, 238 are separated by a channel 248. The channel 248 is at least partially defined by an outer surface 232 of the inner tube 226 and an inner surface 242 of the outer tube 238. Preferably, the outer surface 232 and the inner surface 242 are both substantially smooth. The fluid 21 preferably is injected at an input end 250 of the channel 248, as indicated by arrow “B”. It is also preferred that the material 22 is cooled in a predetermined manner as it moves through the channel 248 from the input end 250 to the output end 252 by a heat transfer subassembly (not shown), to promote solidification of the fluid into the oriented film.

FIG. 5A illustrates an embodiment of a method 171 of the invention. The method 171 begins at step 173, in which the fluid 21 is pumped into the channel 48 at the input end 50 at a predetermined pressure sufficient to push the material 22 to the output end 52. As described above, the channel 48 is at least partially defined by the substantially smooth outer surface 32 of the inner tube 26 and the substantially smooth inner surface 42 of the outer tube 38. Also, the material 22 is subjected to laminar shear at a predetermined rate by rotating one of the inner tube 26 and the outer tube 38 relative to the other, the predetermined rate being selected to promote solidification of the fluid into the oriented film (step 175). In addition, the material 22 is cooled at a predetermined rate as the material moves through the channel 48 from the input end 50 to the output end 52, to promote solidification of the fluid 21 into the oriented film 24 (step 177).

It will be understood that the second and third steps as described above (i.e., steps 175, 177) need not be performed in any particular sequence. Preferably, however, the material is subjected to shear and cooled at substantially the same time.

It is thought that subjecting the fluid to laminar shear has the effect of aligning a large proportion of the crystallites in substantially the same direction. It is also understood that cooling the (oriented) fluid causes such fluid to crystallize, i.e., to solidify. However, as indicated above, and as shown in the examples below, cooling the fluid while it is subjected to laminar shear (i.e., substantially simultaneously) has the beneficial effect of accelerating solidification into the most stable crystal form.

In one embodiment, the material in the channel is cooled by transporting a heat transfer fluid through one or more conduits positioned proximal to the channel to facilitate heat transfer from the material in the channel to said heat transfer fluid. It is preferred that the heat transfer fluid is transported through a number of conduits positioned proximal to the channel, each said conduit being positioned proximal to a preselected length of the channel respectively, the heat transfer fluid having a preselected initial temperature upon introduction thereof into each said conduit respectively to facilitate heat transfer from the material in the channel to the heat transfer fluid (step 179).

It is also preferred that the heat transfer fluid is transported in each said conduit respectively in an overall direction substantially away form the output end and toward the input end (step 181).

### INDUSTRIAL APPLICABILITY

In use, the fluid, which is at a relatively high preselected temperature, is pumped into the channel 48 at the input end 50 at the predetermined pressure. As described above, in one embodiment, the outer tube rotates about the axis, and the material simultaneously is pushed by such pressure from the input end toward the output end. Preferably, the material is cooled at a predetermined rate as the material moves through the channel. The rate at which the material is cooled is selected so as to promote solidification of the fluid into the oriented film. Also, provided that the shear is at a rate within an appropriate range for the material in question, the laminar shear to which the material is subjected as it moves through the channel promotes solidification of the fluid into the oriented film. The speed of rotation of the outer tube is also selected so as to promote solidification of the fluid into the oriented film.

The present invention is illustrated by the following examples.

### Example I

The first sample consisted of cocoa butter. As is known, the fatty acid composition of cocoa butter is approximately as follows:

| | | % w/w |
|---|---|---|
| palmitic acid | (16:0) | 24.7 |
| stearic acid | (18:0) | 35.7 |
| oleic acid | (18:1) | 34.7 |
| linoleic acid | (18:2) | 3.14 |
| linolenic acid | (18:3) | 1.74 |

A sample of cocoa butter was heated to approximately 60° C. The sample was pumped into the channel 48 at the input end 50 at a rate of 30 ml/min. The sample was cooled to the appropriate crystallization temperature in three steps, i.e., by three water jackets connected to three respective water reservoirs. The temperature gradients along the channel (i.e., from input end to output end, left to right as presented) are shown in FIG. 5B. The flow of water through each water jacket was a cross-counter flow, i.e., such flow was directed generally from the outlet end 52 to the input end 50 (as indicated by arrow “A” in FIG. 1A). In this way, the cocoa butter sample was cooled to 22° C.

A shear rate of approximately 340 s⁻¹ was continuously applied to the sample during the crystallization process. The sample was cooled under shear for about 13 minutes.

### Example II

A binary mixture of cocoa butter and milk fat containing approximately 10% (by weight) milk fat was prepared. The fatty acid composition of the binary mixture of cocoa butter and milk fat is approximately as follows:

| | | % w/w |
|---|---|---|
| butyric acid | (4:0) | 0.47 |
| caproic acid | (6:0) | 0.44 |
| caprylic acid | (8:0) | 0.17 |
| capric acid | (10:0) | 0.39 |
| lauric acid | (12:0) | 0.64 |
| myristic acid | (14:0) | 1.51 |
| palmitic acid | (16:0) | 24.8 |
| stearic acid | (18:0) | 35.7 |
| oleic acid | (18:1) | 34.7 |
| linoleic acid | (18:2) | 3.14 |
| linolenic acid | (18:3) | 1.74 |

A sample of binary mixture was heated to approximately 60° C. The sample was pumped into the channel 48 at the input end 50 at a rate of 30 ml/min. The sample was cooled to the appropriate crystallization temperature in three steps, i.e., by three water jackets connected to three respective water reservoirs. The temperature gradients along the channel (i.e., from input end to output end, left to right as presented) are shown in FIG. 5C. The flow of water through each water jacket was a cross-counter flow, i.e., such flow was directed generally from the outlet end 52 to the input end 50 (as indicated by arrow “A” in FIG. 1A). In this way, the binary mixture sample was cooled to 21° C.

A shear rate of approximately 340 s⁻¹ was continuously applied to the sample during the crystallization process. The sample was cooled under shear for about 13 minutes.

### Example III

Palmel 26 is derived from palm oil, and is generally considered a cocoa butter equivalent, or substitute. It is produced by Fuji Oil Co., Ltd. The fatty acid composition of a sample of Palmel 26 has been found to be approximately as follows:

| | | % w/w |
|---|---|---|
| lauric acid | (12:0) | 0.27 |
| myristic acid | (14:0) | 0.91 |
| palmitic acid | (16:0) | 48.5 |
| stearic acid | (18:0) | 4.81 |
| oleic acid | (18:1) | 38.4 |
| linoleic acid | (18:2) | 7.07 |
| linolenic acid | (18:3) | 0.75 |

A sample of Palmel 26 was heated to approximately 50° C. The sample was pumped into the channel 48 at the input end 50 at a rate of 30 ml/min. The sample was cooled to the appropriate crystallization temperature in three steps, i.e., by three water jackets connected to three respective water reservoirs. The temperature gradients along the channel (i.e., from input end to output end, left to right as presented) are shown in FIG. 5D. The flow of water through each water jacket was a cross-counter flow, i.e., such flow was directed generally from the outlet end 52 to the input end 50 (as indicated by arrow “A” in FIG. 1A). In this way, the Palmel 26 sample was cooled to 14° C.

A shear rate of approximately 340 s⁻¹ was continuously applied to the sample during the crystallization process. The sample was cooled under shear for about 13 minutes.

### The Effect of Continuous Laminar Shear on the Solid Fat Content

The crystallization behavior of the samples was followed by measuring the change in solid fat content (SFC) as a function of shear rate, temperature, and time. Crystallized samples were kept at the crystallization temperature for few days to monitor the SFC variation during storage.

As a control the samples were crystallized under static condition (no shear) at the crystallization temperature, 21° C. for cocoa butter containing milk fat, 22° C. and 14° C. for cocoa butter and Palmel 26, respectively. The first solid fat content measurement was made after 35 minutes of storage and was continued for few days until a plateau was reached.

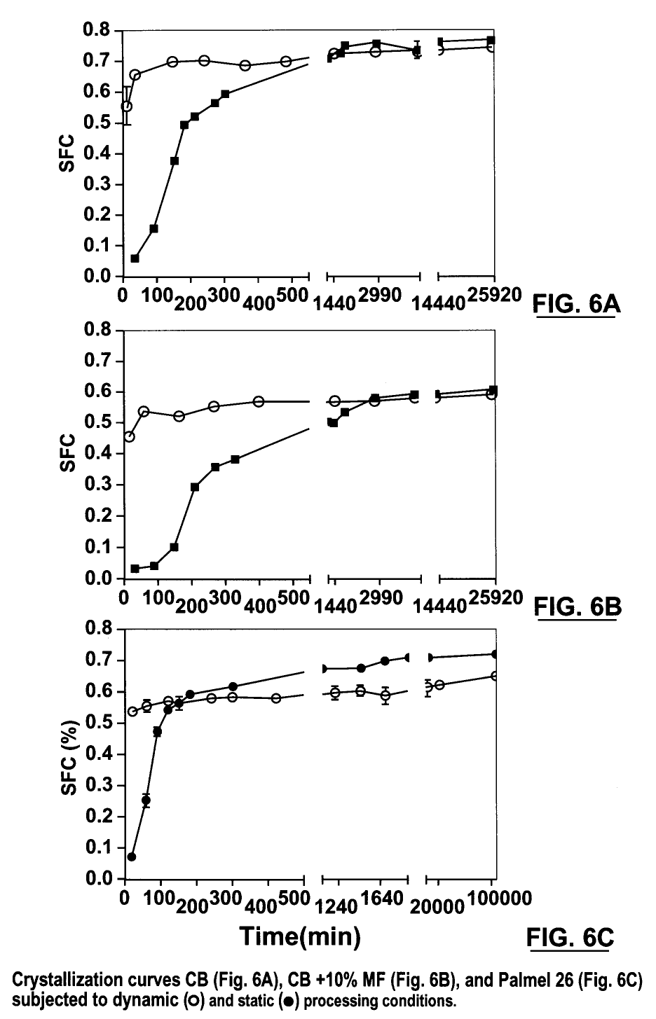

The crystallization curves for the dynamic condition and in the absence of shear are shown in FIGS. 6A, 6B, and 6C. All the samples crystallized under shear show a slight increment in the SFC evaluation during the first 60 minutes of storage and reached a plateau of SFC. In contrast, in the samples crystallized without shear, the constant value of SFC is obtained after a longer period of time. As shown, sheared cocoa butter has 65% SFC after 35 minutes of storage and reached a plateau of 70% SFC after two hours while under static condition it requires 20 hours to reach this constant SFC value.

This sharp increase in the amount of solid fat crystals, and thus the degree of crystallization in the dynamic condition is an evident that the laminar shear applied to the samples (i.e., for 13 minutes only) accelerated the crystallization rate.

### The Effect of Continuous Shear on the Polymorphic Behavior of the Samples

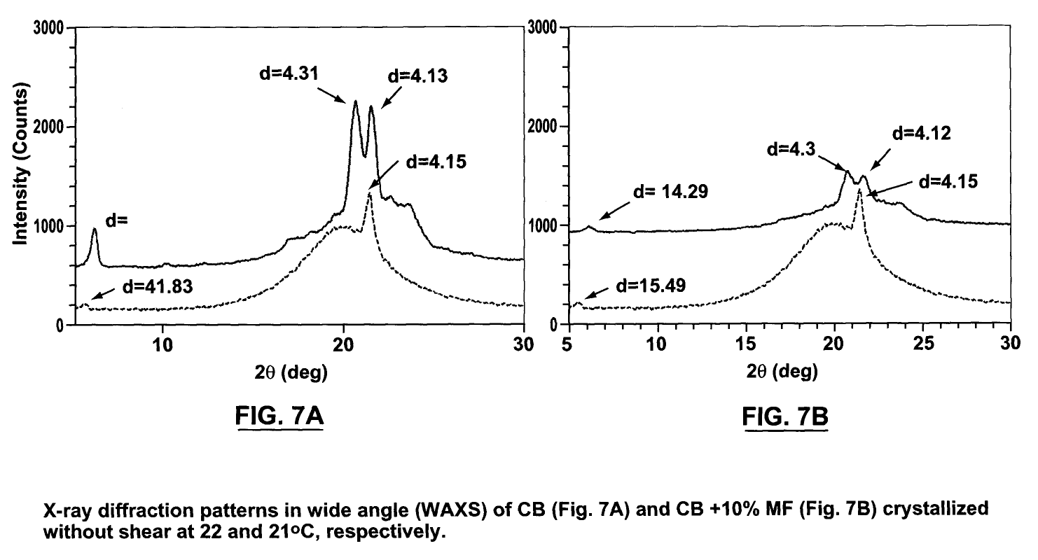

The polymorphic modifications of crystallized samples were determined by powder X-ray diffraction (XRD). FIGS. 7A and 7B show typical X-ray diffraction patterns for CB and CB+10% MF samples under static (no shear) conditions in the WAXS and SAXS regions. After 15 minutes of static crystallization, both samples exhibited one small diffraction peak in the WAXS region at 21.4° 2θ (4.15 \acute{Å}), characteristic of form II (α). Changes in the position of the diffraction peaks were detected in this region after 55 minutes; the diffraction peak at 4.15 \acute{Å} faded away and two new peaks appeared at 20.6° 2θ (4.3 \acute{Å}) and 21.5° 2θ (4.1 \acute{Å}), characteristic of form IV (β′₂). This modification of diffraction patterns indicates that the polymorphic structures of the samples were in process of transforming from form II to form IV during the experiment and remained constant for 24 hours. After 24 hours, a weak peak disappeared at 22.5° 2θ (3.94 \acute{Å}), indicating a partial transformation of the metastable form. The sharp peak of form V was not observed until 48 hours, which is evidence of transformation to form V after two days under static conditions.

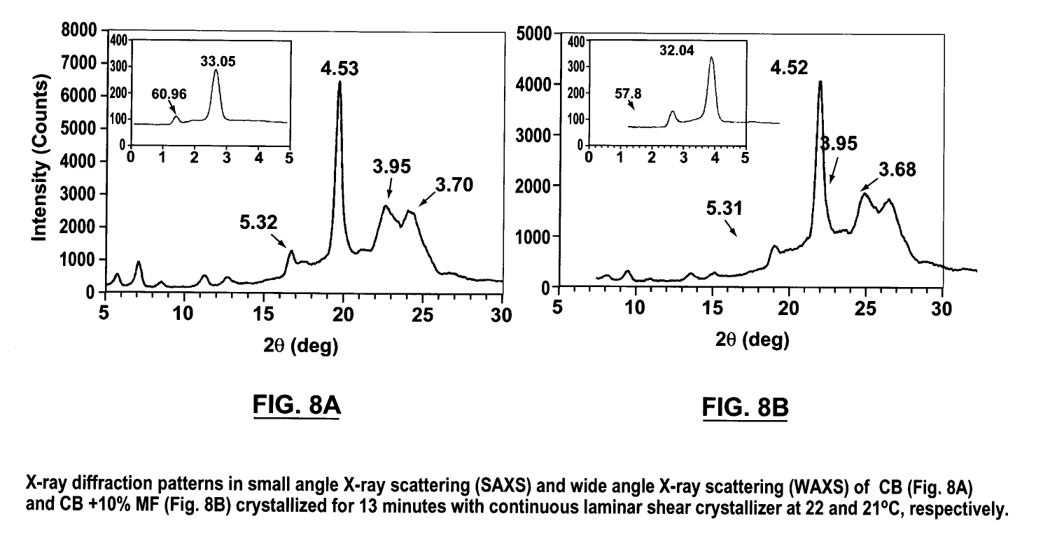

With the aim of studying the effect of laminar shear on the polymorphism of crystallized samples, XRD experiments were also carried out on the samples crystallized dynamically as early as possible after the crystallization process. FIGS. 8A and 8B present the X-ray diffraction pattern of CB (a) and CB+10% MF (b) at time 0. In crystallized CB, two new diffraction peaks appeared in SAXS at 1.5° 2θ (61 \acute{Å}) and 2.7° 2θ (33.05 \acute{Å}), and one very sharp peak emerged in WAXS at 19.9° 2θ (4.53 \acute{Å}) accompanied by at least two smaller peaks on the larger 20 side, one at 22.5° 2θ (3.95 \acute{Å}) and the other at 24.1° 2θ (3.70 \acute{Å}), which are characteristic of the form βV polymorph. One can notice the appearance of similar peaks in the binary mixture of cocoa butter and milk fat (FIG. 8B), which are evidence of a βV polymorphic form in this sample as well. This result demonstrates that by using the continuous laminar shear crystallizer, fats can be crystallized in the more stable polymorphic form in less than 15 minutes, i.e. laminar shear improved the formation of the desirable stable form.

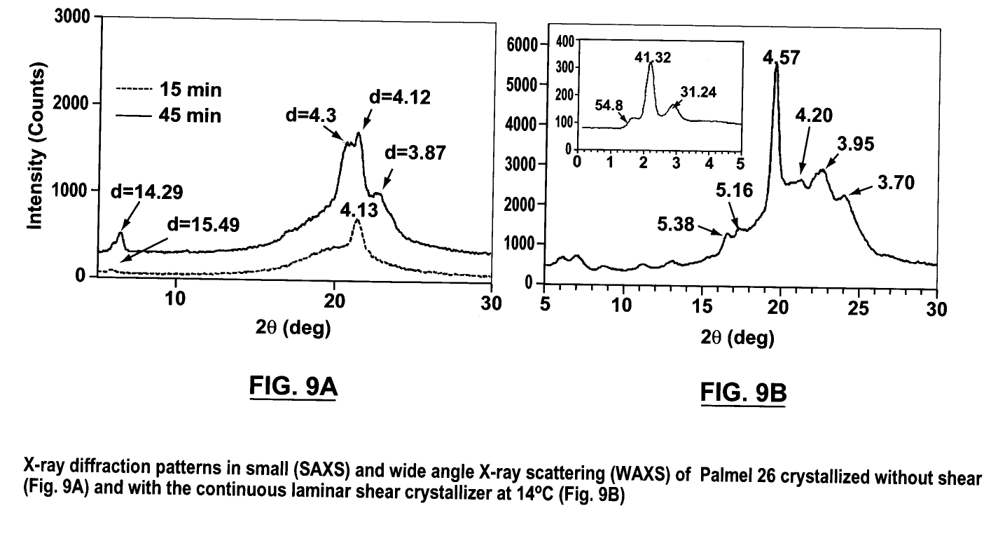

Like many other fats, Palmel 26 can be crystallized in different polymorphic phases. Comparing the effect of applied shear on the polymorphic form of this sample FIGS. 9A and 9B present two typical XRD diffraction patterns of Palmel 26 crystallized without shear (a) and under shear (b) at 14° C. For the static condition (FIG. 9A), the observed wide angle reflection corresponds to the form a for the first 30 minutes of crystallization, a short spacing at 21.5° 2θ (4.13 \acute{Å}). This sample converted to the characteristic 20.7° 2θ (4.30 \acute{Å}), 21.5° 2θ (4.12 \acute{Å}), and 23° 2θ (3.867 \acute{Å}), pattern of β′ form after 45 minutes.

Under dynamic conditions the X-ray diffraction study reveals three peaks in the SAXS region corresponding to 1.6° 2θ (54.8 \acute{Å}), at 2.1° 2θ (41.32 \acute{Å}), and 2.8° 2θ (31.24 \acute{Å}). At the same time, in the WAXS region one can notice a very strong peak at 19.5° 2θ (4.54 \acute{Å}) and three medium peaks at 21.1° 2θ (4.203 \acute{Å}), 22.5° 2θ (3.945 \acute{Å}), and 24° 2θ(3.702 \acute{Å}).

Consequently, by using the continuous laminar shear crystallizer all the samples were crystallized in the more stable polymorphic form in less than 15 minutes. Accordingly, applying laminar shear accelerated, or promoted, the formation of the desirable stable form.

### The Effect of Continuous Shear on the Thermal Behavior of the Samples

The thermal behavior of crystallized samples, both static and dynamic conditions, was studied by differential scanning calorimetry, DSC.

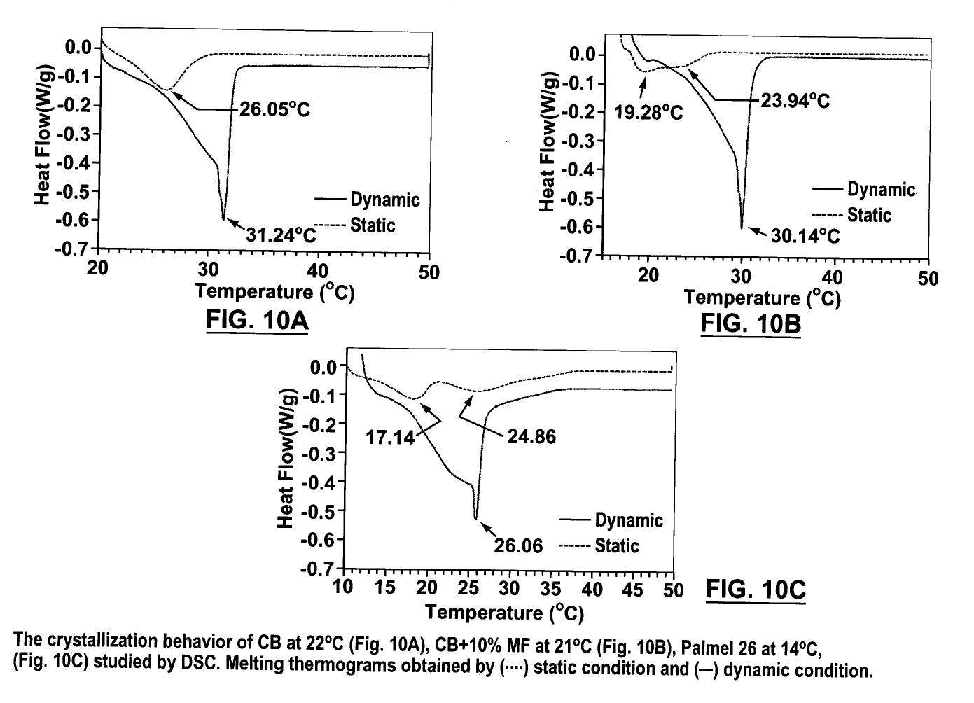

The predominant polymorphic form was determined from the peak melting temperature based on the published studies (Larsson 1994, Wille and Lutton 1966, Van Malsen et al. 1999). The peak melting temperatures of the processed samples under shear and static conditions are shown in FIGS. 10A-10C. Cocoa butter crystallized statically at 22° C. for one hour showed a single broad peak at 26.05° C. indicating the presence of form IV. Under the static condition the CB and MF mixture and Palmel 26 displayed two peak melting points correlated with transition of each polymorph from its less stable form to a more stable phase.

On the other hand, FIGS. 10A-10C also show the effects of laminar shear on the melting profile of all the samples. With the experimental set up used in this study all the samples crystallized under dynamic conditions have a high melting form. This range corresponds to the existence of a β form, indicating that the presence of shear affects the crystalline structure of fats. It appears that the mechanical work applied to the samples accelerated transformation of lower stability phases to higher stability phases.

### The Effect of Continuous Shear on Crystalline Orientation

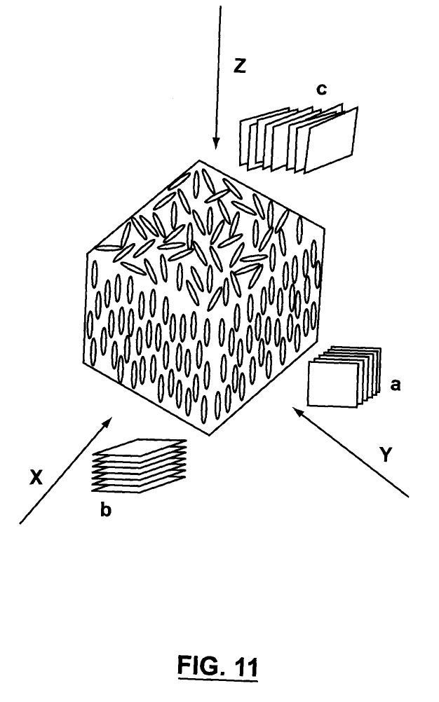

An X-ray beam was passed through the dynamic crystallized sample in YZ, YX, and XZ planes to study the effect of the continuous laminar shear on crystalline orientation in “a” (i.e., parallel to the shearing surface direction), “b” (i.e., perpendicular to the shearing surface direction), and “c” (i.e., parallel to the flow direction) (Gullity 2001). No orientation effect was shown in YX plane (c), but a clear orientation was observed in YZ (a), and XZ (b), planes (FIG. 11).

The crystalline orientation in XZ plane is in agreement with the previous report by Mazzanti et al. (2003). However the finding of orientation in YZ plane is in contrast to the report by MacMillan et al. (2002). The use of a different shear system and also differences in the experimental procedures (e.g., shear rate), may have led to this inconsistency. Since orientation was similar in YZ and XZ planes, only the result in XZ is further discussed below.

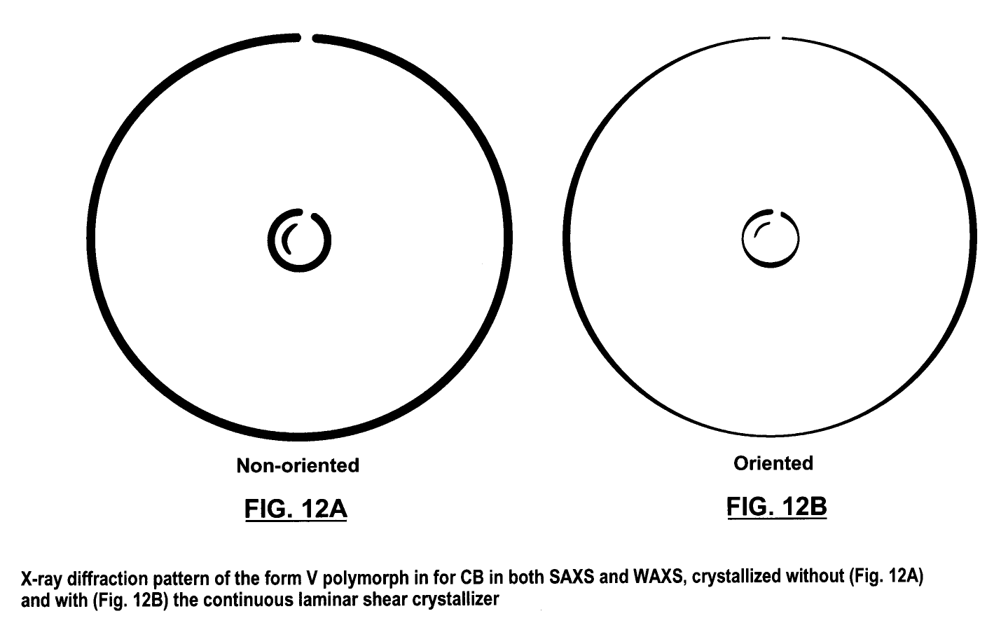

To illustrate the effect of applied shear by the laminar shear crystallizer, FIGS. 12A and 12B show characteristic small and wide angle diffraction rings from CB crystals crystallized statically (FIG. 12A) and dynamically (FIG. 12B) into phase V. FIGS. 12A and 12B present the characteristic small angle (002) and there is a perfectly visible peak in the wide angle region at d=4.54 \acute{Å}. This peak is typical of β polymorphism, which is a crystallization subcell type adopted by form V. In addition, the anisotropy of the scattering intensity around the rings in both short and long spacing clearly indicates crystallite orientation.

In the oriented sample, a portion of the Debye ring is missing because the crystal network does not display orientation in the directions which diffract those parts of the ring, showing the fact that the agglomerating forces between the crystallites have been overcome by the shearing forces, allowing the crystallites to segregate.

The diffraction rings at small and wide angles are oriented in orthogonal direction, as expected from the origin in the crystal, relative to the triclinic crystalline structure. The same results have been observed for the other samples (i.e., the mixture of CB and MF and Palmel 26).

### Azimuthal Plot

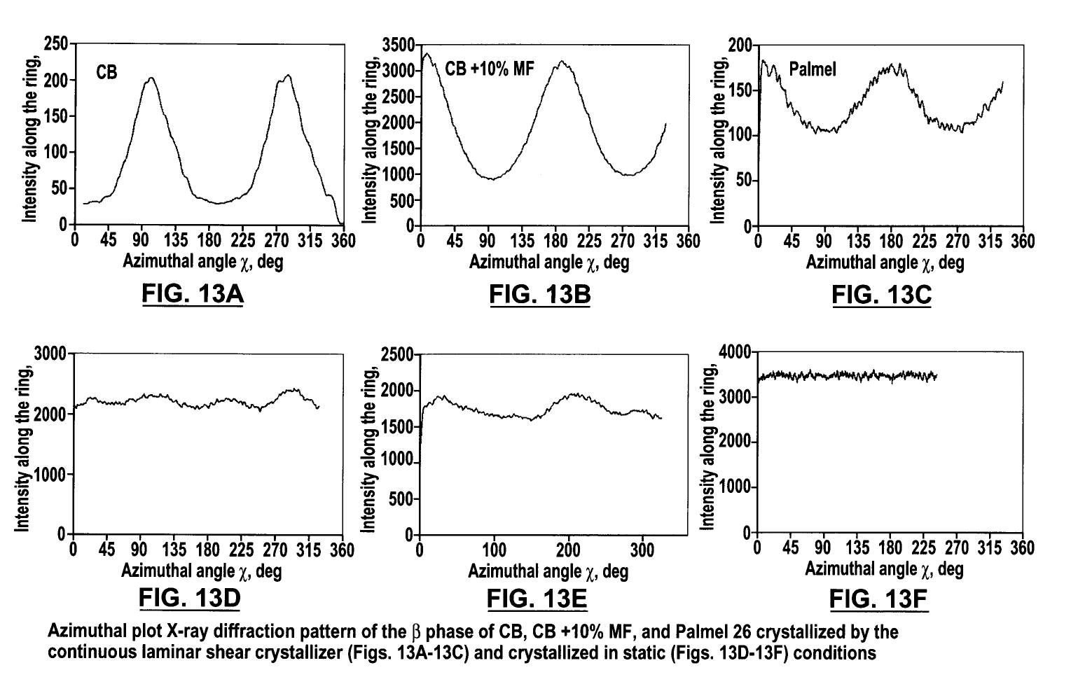

To evaluate the crystalline orientation in the sample, azimuthal plots, corresponding to changes in the normalized intensity around the Debye ring and derived from the 2D images, were determined. The obtained azimuthal plots for all the samples crystallized in the laminar shear crystallizer and under static conditions are shown in FIGS. 13A-13F.

The azimuthal profile showed peaks that are separated by 180° and reflect an acceptable oriented portion in dynamic conditions compared to the static conditions, which allows a meaningful value for the azimuthal width to be computed. In order to evaluate the degree of orientation in the samples, the full width at half maximum (Δχ) was obtained by fitting a Gaussian distribution to the azimuthal curves. Analysis of the distribution showed a good fit of the data to the Gaussian curve. As well, distribution to the data orientation ratio χᵣ was determined considering the proportion of oriented/unoriented materials in each crystallized sample. Table 2 presents the degree of orientation (Δχ) and also the orientation ratio χᵣ for cocoa butter, cocoa butter+10% milk fat, and Palmel 26 crystallized under static and dynamic conditions. However, even if the method described was useful in the analysis, it suffers from some limitations as any other measuring tool. For instance when the azimuthal plots were not smooth enough, in the static condition, the program could not calculate the actual full width half maximum value and the area under the curve because of the noise. This is why these values are missing for CB in Table 2.

All the materials studied displayed a strong orientation by presenting a large orientation ratio and small azimuthal width when crystallized in the continuous laminar shear crystallizer. Since orientation is a result of the competition between shear forces and disordering forces, the observed orientation suggests that particles formed by the crystallizer are most likely oriented and the applied shear force was able to prevent them from forming non-oriented clusters.

TABLE 2
Degree of orientation (Δχ) and the orientation ratio χᵣ for cocoa
butter, cocoa butter +10% milk fat, and Palmel 26 crystallized
under static and dynamic conditions.

| | Static | | Dynamic | |
|---|---|---|---|---|
| Sample | Δχ | χᵣ (%) | Δχ | χᵣ (%) |
| Cocoa butter | ND | ND | 56 | 78.5 |
| Cocoa Butter/10% Milk fat | 147.31 | 35.95 | 74.23 | 63.31 |
| Palmel 26 | 169.1 | 15.2 | 79.68 | 52.26 |

*ND = Not determined

Based on the foregoing, it can be seen that the apparatus of the invention has produced a film of substantially crystallographically oriented material, for each sample.

### Example IV

Gels are an important class of materials which are widely used in industry and due to biocompatibility, ease of manipulation and low price, are used widely in the food, pharmaceutical and photograph industries. Most studies on the barrier and mechanical properties of gel have focused on the gelation process during cooling or heating. To study the effect of laminar shear during cooling on these properties, a solution of gelatin in water was pumped through the crystallizer.

A commercially available gelatin was dissolved in hot water to provide a gelatin solution at concentrations of 25% in 60° C. The solution was pumped through the gap between the outer and the inner tubes at a 40 ml/min flow rate. By means of the three water jackets positioned inside the crystallizer, the sample was cooled in three steps. A cross counter flow of water with oil flow at 500 ml/min flow rate was sent through each water jacket.

While a shear rate of 340 s⁻¹ was continuously applied to the sample during the crystallization process, it cooled from 60° C. to 30° C. at the first step, from 30° C. to 20° C. at the second step and from 20° C. to 10° C. by the third water jacket. The sheet of gel was obtained continuously.

Based on these results, it appears that subjecting gel to laminar shear and cooling the gel as described may also provide beneficial results. Good results may also be achieved with other polymorphic materials (e.g., proteinaceous materials and polysaccharides). Therefore, another interesting functionality of the laminar shear crystallizer was developed. However, more research needs to be done to study the effect of laminar shear orientation, concentration, and cooling rate on the structure of the gel.

Any element in a claim that does not explicitly state “means for” performing a specified function, or “step for” performing a specified function, is not to be interpreted as “means” or “step” clause as specified in 35 U.S.C. §112, paragraph 6.

It will be appreciated by those skilled in the art that the invention can take many forms, and that such forms are within the scope of the invention as claimed. Therefore, the spirit and scope of the appended claims should not be limited to the descriptions of the preferred versions contained herein.

### REFERENCES

Gullity B. D., Stock S. R., (2001). Elements of X-ray diffraction. 3^{rd} edition. New Jersey: Prentice Hall.
Larsson K., (1994). Lipids-molecular organization, physical functions and technical applications. The Oily Press LTD, Sweden.
MacMillan S. D., Roberts K. J., Rossi A., Wells M. A., Polgreen M. C., and Smith I. H., (2002). In Situ Small Angle X-ray Scattering (SAXS) Studies of Polymorphism with the Associated Crystallization of Cocoa Butter Fat Using Shearing Conditions. Crystal Growth and Design, 2:221-226.
Mazzanti G., Guthrie S. E., Sirota E. B., Marangoni A. G., Idziak S. H. J., (2003). Orientation and phase transitions of fat crystals under shear. Crystal Growth design, 3(5):721-725
Mazzanti G., Guthrie S. E., Sirota E. B., Marangoni A. G., Idziak S. H. J., (2005). Crystallization of bulk fats under shear, in Soft Materials: Structure and Dynamics, edited by J. R. Dutcher and A. G. Marangoni. Marcel Dekker, New York, USA. 279-298
Mazzanti G., (2004). X-Ray diffraction study on the crystallization of fats under shear. Ph.D. thesis. University of Guelph, Guelph, ON. Canada.
Van Malssen K. F., Van Langevelde A., Peschar R., and Schenk H., (1999). Phase behavior and extended phase scheme of static cocoa butter investigated with real-time X-ray powder diffraction. Journal of American Oil Chemists' Society, 76(6):669-674.
Willie R. L., Lutton E. S. (1966). Polymorphism of cocoa butter. Journal of American Oil Chemists' Society, 43:491-496.

We claim:

1. An apparatus for solidifying a fluid comprising a material to form an oriented film, the apparatus comprising:
an inner tube substantially symmetrical with respect to an axis thereof, the inner tube comprising an outer diameter defined by a substantially smooth outer surface thereof and an inner diameter defined by an inner surface thereof;
an outer tube substantially symmetrical with respect to the axis, the outer tube comprising an inner diameter defined by a substantially smooth inner surface thereof;
the inner and outer tubes being positioned substantially coaxially to at least partially define a channel therebetween, the channel extending between input and output ends thereof;
a selected one of the tubes being adapted for rotation thereof about the axis such that the selected tube is movable relative to the other of said tubes;
the fluid being injectable into the channel at the input end under a predetermined pressure sufficient to push the material to the output end, whereby the material is subjected to laminar shear at a predetermined rate due to rotation of the selected tube at a preselected speed, said predetermined rate being selected to promote solidification of the fluid into the oriented film as the material moves through the channel toward the outer end; and
a heat transfer subassembly for modifying the material's temperature to promote solidification of the fluid into the oriented film.

2. An apparatus according to claim 1 in which the channel is substantially uniform between the input and output ends thereof for promoting solidification of the fluid into the oriented film.

3. An apparatus according to claim 1 in which the inner surface of the outer tube and the outer surface of the inner tube are substantially parallel to each other.

4. An apparatus according to claim 1 in which the heat transfer subassembly is for cooling the material in the channel in a predetermined manner to promote solidification of the fluid into the oriented film.

5. An apparatus according to claim 4 in which the heat transfer subassembly comprises at least one conduit positioned proximal to the inner surface of the inner tube and a heat transfer fluid transportable through said at least one conduit to facilitate heat transfer between the material in the channel and said heat transfer fluid.

6. An apparatus according to claim 5 in which the heat transfer fluid is directed through said at least one conduit substantially from the output end to the input end of the channel.

7. An apparatus according to claim 5 in which the heat transfer subassembly is adapted to cool the material in accordance with at least one preselected temperature gradient along at least one preselected length of the channel to promote solidification of the fluid into the oriented film.

8. An apparatus according to claim 5 in which the heat transfer fluid is introduced into said at least one conduit at a predetermined temperature, for cooling the material in a preselected length of the channel proximal to said at least one conduit to a predetermined extent to promote solidification of the fluid into the oriented film.

9. An apparatus according to claim 4 in which the heat transfer subassembly comprises a plurality of conduits, each said conduit being positioned proximal to a preselected length of the channel, and a heat transfer fluid transportable through each said conduit respectively to facilitate heat transfer between the material in the channel and said heat transfer fluid.

10. An apparatus according to claim 9 in which each said conduit is adapted to cool the material in each said preselected length of the channel respectively in accordance with preselected temperature gradients respectively, said temperature gradients being selected to promote solidification of the fluid into the oriented film.

11. An apparatus according to claim 9 in which the heat transfer fluid, upon introduction thereof into each said conduit respectively, has a preselected initial temperature, each said preselected initial temperature respectively being selected for cooling the temperature of the material in each said preselected length of the channel to a preselected extent respectively to promote solidification of the fluid into the oriented film.

12. An apparatus according to claim 11 in which the preselected initial temperature of the heat transfer fluid for each said conduit is respectively determined according to the position of each said conduit relative to the input and output ends of the channel.

13. An apparatus according to claim 9 in which the heat transfer fluid is directed through each said conduit in an overall direction substantially away from the output end and toward the input end.

14. An apparatus according to claim 1 in which the outer tube additionally comprises at least one port for permitting sampling of the material in the channel.

15. A method of solidifying a fluid comprising a material to form an oriented film, the method comprising:
(a) pumping the fluid into a channel at an input end thereof at a predetermined pressure sufficient to push the material to an output end of the channel, the channel being at least partially defined by a substantially smooth outer surface of an inner tube and a substantially smooth inner surface of an outer tube;
(b) subjecting the material to laminar shear at a predetermined rate by rotating one of the inner tube and the outer tube relative to the other, said predetermined rate being selected to promote solidification of the fluid into the oriented film; and
(c) cooling the material at a predetermined rate as the material moves through the channel from the input end to the output end to promote solidification of the fluid into the oriented film.

16. A method according to claim 15 in which the material in the channel is cooled by transporting a heat transfer fluid through at least one conduit positioned proximal to the channel to facilitate heat transfer from the material in the channel to said heat transfer fluid.

17. A method according to claim 15 in which the material in the channel is cooled by transporting a heat transfer fluid through a plurality of conduits positioned proximal to the channel, each said conduit being positioned proximal to a preselected length of the channel respectively, the heat transfer fluid having a preselected initial temperature upon introduction thereof into each said conduit respectively to facilitate heat transfer from the material in the channel to said heat transfer fluid.

18. A method according to claim 17 in which the material in the channel is cooled by pumping the heat transfer fluid in each said conduit respectively in an overall direction substantially away from the output end and toward the input end.

19. A method according to claim 15 in which steps (b) and (c) are performed substantially simultaneously.

20. An oriented film solidified from a fluid comprising a material, the oriented film being produced by the steps of:
(a) pumping the fluid into a channel at an input end thereof at a predetermined pressure sufficient to push the material to an output end of the channel, the channel being at least partially defined by a substantially smooth outer surface of an inner tube and a substantially smooth inner surface of an outer tube;
(b) subjecting the material to laminar shear at a predetermined rate by rotating one of the inner tube and the outer tube relative to the other, to promote solidification of the fluid into the oriented film; and
(c) cooling the material at a predetermined rate as the material moves through the channel from the input end to the output end to promote solidification of the fluid into the oriented film.

21. An oriented film according to claim 20 in which the method comprises steps (b) and (c) which are performed substantially simultaneously.

22. An apparatus for solidifying a fluid comprising a material to form an oriented film, the apparatus comprising:
an inner tube substantially symmetrical with respect to an axis thereof, the inner tube comprising an outer diameter defined by a substantially smooth outer surface thereof;
an outer tube substantially symmetrical with respect to the axis, the outer tube comprising an inner diameter defined by a substantially smooth inner surface thereof and an outer diameter defined by an outer surface thereof;
the inner and outer tubes being positioned substantially coaxially to at least partially define a channel therebetween, the channel extending between input and output ends thereof;
a selected one of the tubes being adapted for rotation thereof about the axis such that the selected tube is movable relative to the other of said tubes;
the fluid being injectable into the channel at the input end under a predetermined pressure sufficient to push the material to the output end, whereby the material is subjected to laminar shear as the material moves through the channel toward the outer end due to movement of the selected tube relative to the other said tube, said laminar shear at least partially causing the fluid to solidify into the oriented film; and
a heat transfer subassembly for modifying the material's temperature to promote solidification of the fluid into the oriented film.
